(19) United States
(12) Patent Application Publication
(10) Pub. No.: US 2015/0185408 A1
(43) Pub. Date: Jul. 2, 2015

(54) PROTECTIVE COVER

(71) Applicants: Sung-Chun Hsu, Hsin-Chu (TW); Chun-Chung Hsiao, Hsin-Chu (TW)

(72) Inventors: Sung-Chun Hsu, Hsin-Chu (TW); Chun-Chung Hsiao, Hsin-Chu (TW)

(73) Assignee: Young Lighting Technology Inc., Hsin-Chu (TW)

(21) Appl. No.: 14/555,697

(22) Filed: Nov. 28, 2014

(30) Foreign Application Priority Data
Jan. 2, 2014 (TW) 103100060

(51) Int. Cl. F21V 8/00; G06F 1/16; H05K 5/03

(52) U.S. Cl. CPC G02B 6/0088; G02B 6/0036; G02B 6/005; G02B 6/0046; G02B 6/0073; G02B 6/007; G02B 6/0083; G02B 6/009; H05K 5/03; G06F 1/1613

(57) ABSTRACT

A protective cover is adapted to cover a display region of a mobile electronic device. The protective cover includes a fixed side, a movable side, and a flexible portion connecting the fixed side and the movable side. The fixed side is adapted to detachably fix the mobile electronic device. The movable side is adapted to cover the display region and has a transparent plate and a light source device. The transparent plate has a first surface, a second surface opposite to the first surface, and at least one light incident surface capable of connecting the first and second surfaces. The light source device is disposed adjacent to the light incident surface. Light generated from the light source device enters the transparent plate and then reaches the display region through the first surface of the transparent plate. The display region receives the light and displays an image through the transparent plate.

### CROSS-REFERENCE TO RELATED APPLICATION

This application claims the priority benefit of Taiwan application serial no. 103100060, filed on Jan. 2, 2014. The entirety of the above-mentioned patent application is hereby incorporated by reference herein and made a part of this specification.

### BACKGROUND OF THE INVENTION

1. Field of the Invention

The invention relates to a protective cover and, more particularly, to a protective cover capable of providing an illumination light source device.

2. Description of Related Art

The mobile electronic devices become more and more diversified following the rapid change of science and technology, such as smart phones, tablet PCs, electronic books, and so on. Compared to the conventional desktop computers or notebook computers, the mobile electronic devices have the advantage of portability. However, while the mobile electronic devices are being carried, the mobile electronic devices are likely to be hit by various external forces or fall on the ground, resulting in the damage to the casings of the devices or malfunction of the devices. In order to resolve said issues, various protective covers adapted to protect every kind of mobile electronic devices have been developed and are available on the market currently, and thereby damages to the mobile electronic devices may be reduced.

However, the existing protective cover can only provide functions of protection and impact mitigation and cannot provide any external light source for the mobile electronic device when the ambient illumination in the environment is insufficient. Specifically, if the mobile electronic device is equipped with the display panel of the total reflection type or the transflective display panel, insufficient ambient illumination in the environmental may cause the display module of the mobile electronic device not to display images in an effective manner. Currently, users can solve the problem of insufficient illumination through carrying additional light source devices (for example, planar reading lights). However, the users have to hold the mobile electronic device in one hand and simultaneously hold the additional light source device in the other hand when using the mobile electronic device, which causes great inconvenience to the users. Hence, a protective cover capable of providing the light source device and performing the protection function simultaneously is required.

China patent no. CN102254455 discloses an electronic book structure with a front light source. China patent no. CN102208155 discloses an electronic book that includes a lighting body. Taiwan patent no. M380553 discloses an electronic book comprising a front light module. Taiwan patent no. M460320 discloses a protective shell structure. Taiwan patent no. M289038 discloses a protective cover of a mobile phone.

### SUMMARY OF THE INVENTION

Accordingly, the invention is directed to a protective cover which protects a mobile electronic device and provides an extra light source device to the mobile electronic device.

The other purpose and advantages of the invention will be further understood through the technical features disclosed by the invention.

In order to achieve one or part or all of the aforementioned purposes or other purposes, an embodiment of the invention provides a protective cover which is adapted to protect a mobile electronic device and illuminate a display region of the mobile electronic device. The protective cover includes a fixed side, a movable side, and a flexible portion connecting the fixed side and the movable side. The fixed side is adapted to detachably fix the mobile electronic device. The movable side is adapted to cover the display region of the mobile electronic device and has a transparent plate and a light source device. The transparent plate has a first surface, a second surface opposite to the first surface, and at least one light incident surface connecting the first surface and the second surface. The light source device is disposed adjacent to the light incident surface. The light generated from the light source device enters the transparent plate through the light incident surface and then reaches the display region through the first surface of the transparent plate. The display region is adapted to receive the light and display an image through the transparent plate.

According to one embodiment of the invention, the movable side further includes a frame with an opening. The frame is connected to the flexible portion, and the transparent plate is fixed to the frame and covers the opening.

According to one embodiment of the invention, the light source device is buried inside the frame.

According to one embodiment of the invention, the transparent plate has at least one reflection layer, the transparent plate has at least one side surface connecting the first surface and the second surface, and the at least one reflection layer is disposed on the at least one side surface.

According to one embodiment of the invention, the transparent plate has an optical film, and the optical film is disposed on the first surface or the second surface, such that the light from the light source device enters the display region.

According to one embodiment of the invention, the transparent plate has a plurality of optical micro structures on the first surface or the second surface, so as to guide the light in the transparent plate to the display region.

According to one embodiment of the invention, the optical micro structures are disposed on the first surface and the second surface of the transparent plate simultaneously.

According to one embodiment of the invention, the first surface and the second surface are not parallel to each other.

According to one embodiment of the invention, the light source device includes a circuit board and a plurality of light-emitting elements mounted on the circuit board.

According to one embodiment of the invention, the light-emitting elements are light emitting diodes (LED).

According to one embodiment of the invention, the light source device is a cold cathode fluorescent lamp (CCFL).

According to one embodiment of the invention, the protective cover further includes an electrical connector disposed on the fixed side or the movable side and coupled to the light source, such that the electrical connector is adapted to electrically connect the light source device with the mobile electronic device.

According to one embodiment of the invention, the protective cover further includes a cable connector coupled to the light source and adapted to electrically connect the light source device with the mobile electronic device.

According to one embodiment of the invention, the protective cover further includes an external power supply that is disposed on the fixed side and coupled to the light source device.

According to one embodiment of the invention, the external power supply is buried inside the fixed side.

According to one embodiment of the invention, the external power supply is disposed adjacent to the fixed side.

According to one embodiment of the invention, the fixed side further includes at least one fixed portion configured to fix the mobile electronic device.

As described above, in the aforementioned embodiments of the invention, the protective cover covers and protects the mobile electronic device from being hit by external forces, so as to reduce damages to the casing of the mobile electronic device or prevent malfunction of the mobile electronic device. Besides, the protective cover provides the illumination light source device to the mobile electronic device. Hence, when there is no ambient light source, the mobile electronic device with the reflective display or the transflective display can still be normally used together with the illumination light source device provided by the protective cover.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

FIG. 1A to FIG. 1C are perspective views illustrating several implementations of a protective cover and a mobile electronic device according to one embodiment of the invention.

FIG. 2A to FIG. 2G are schematic diagrams of a structure of a transparent plate according to several embodiments of the invention.

FIG. 3A to FIG. 3F are perspective views illustrating several implementations of a protective cover according to another embodiment of the invention.

FIG. 4 is a perspective view of a protective cover according to another embodiment of the invention.

### DESCRIPTION OF THE EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

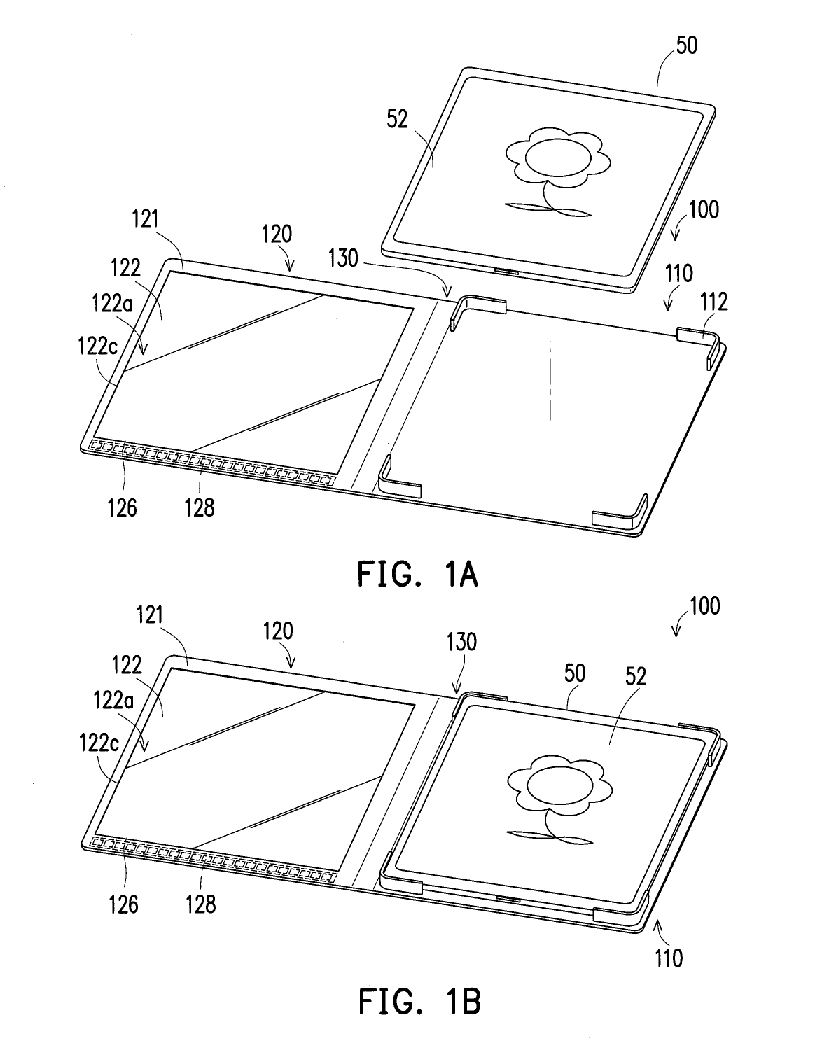

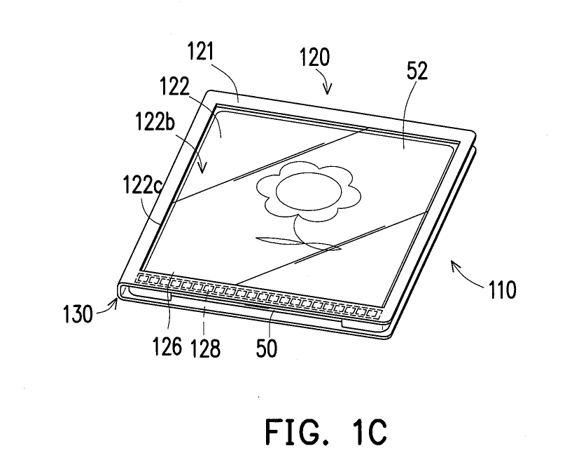

FIG. 1A to FIG. 1C are perspective views illustrating several implementations of a protective cover and a mobile electronic device according to one embodiment of the invention. As shown in FIG. 1A to FIG. 1C, the protective cover 100 provided in the embodiment is used to cover a mobile electronic device 50 and illuminate a display region 52 of the mobile electronic device 50. The protective cover 100 provided in the embodiment includes a fixed side 110, a movable side 120, and a flexible portion 130. The fixed side 110 detachably fixes the mobile electronic device 50. The movable side 120 is adapted to cover the display region 52 of the mobile electronic device 50. The flexible portion 130 locates between the fixed side 110 and the movable side 120, and connects the fixed side 110 and the movable side 120 in a bendable way, so that the protective cover 100 is unfolded through the deformation of the flexible portion 130 and exposes the mobile electronic device 50 to a user. Alternatively, the movable side 120 covers the display region 52 of the mobile electronic device 50 through the deformation of the flexible portion 130, so as to render protection on the display region 52 of the mobile electronic device 50. In the embodiment, the fixed side 110 includes at least one fixed portion 112, and the fixed portion 112 may flexibly fix, clamp, or latch the mobile electronic device 50; however, the invention is not limited thereto. Besides, the flexible portion 130 is made of rubber, leather, or other bendable materials, for instance.

In the embodiment, the movable side 120 has a frame 121, a transparent plate 122, and a light source device 128, wherein the frame 121 has an opening (not numbered). The transparent plate 122 is fixed to the frame 121 and covers the opening. The frame 121 surrounds the transparent plate 122 and is connected to the flexible portion 130. The transparent plate 122 has a first surface 122a, a second surface 122b opposite to the first surface 122a, and at least one light incident surface 126 connecting the first surface 122a and the second surface 122b, as illustrated in FIG. 1C. The light source device 128 is buried inside one side edge of the frame 121 and is disposed adjacent to the light incident surface 126 of the transparent plate 122. The light source device 128 can generate light that enters the transparent plate 122 through the light incident surface 126 and then reaches the display region 52 of the mobile electronic device 50 through the second surface 122b of the transparent plate 122. After the display region 52 receives the light from the transparent plate 122 of the movable side 120, the display region 52 displays an image through the transparent plate 122. The area of the transparent plate 122 may be larger than or equal to the area of the display region 152. The transparent plate 122 and the light source device 128 on the movable side 120 can collectively act as a planar light source to provide the display region 52 with the required illumination.

In the embodiment, the light source device 128 is a LED light bar, a cold cathode fluorescent lamp (CCFL), or other light-emitting elements providing the linear light source device, but the invention is not limited thereto. Besides, the material of the main body of the transparent plate 122 includes but is not limited to polymethyl methacrylate (PMMA), polycarbonate (PC), or glass. Besides, FIG. 1A to FIG. 1C only illustrate one light source device 128. However, additional light source devices (not illustrated) can also be disposed adjacent to the side surface 122c of the transparent plate 122 in the invention, so as to provide great brightness. The side surface 122c connects the first surface and the second surface. These additional light source devices can also be buried inside other side edges of the frame 121, which should not be construed as a limitation to the invention.

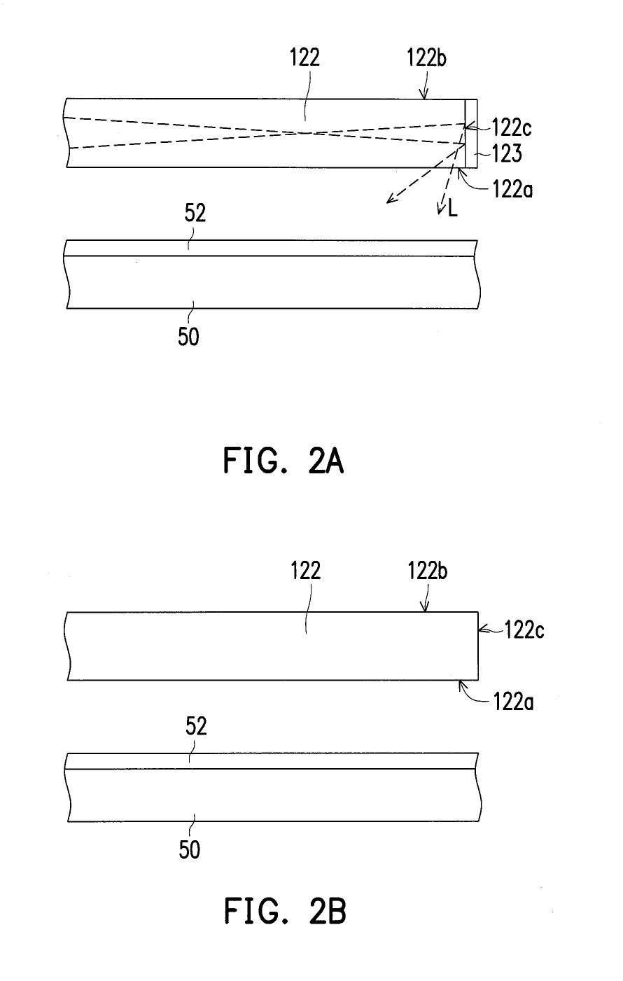

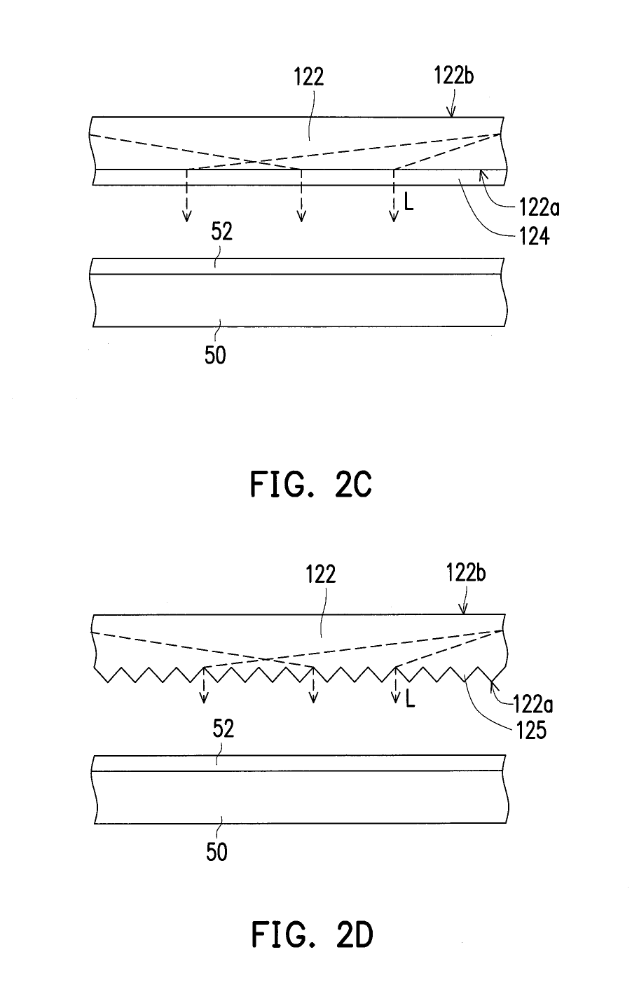

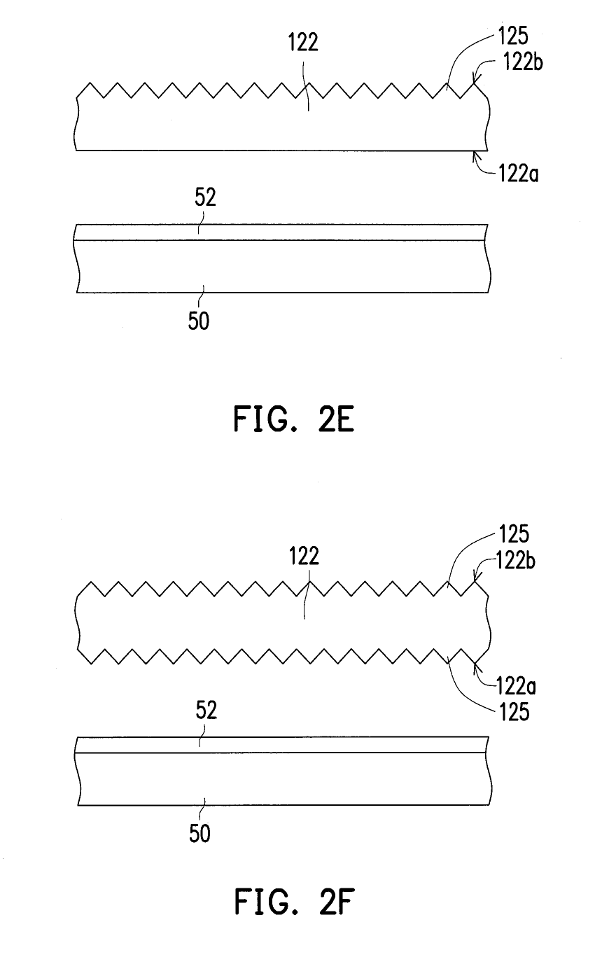

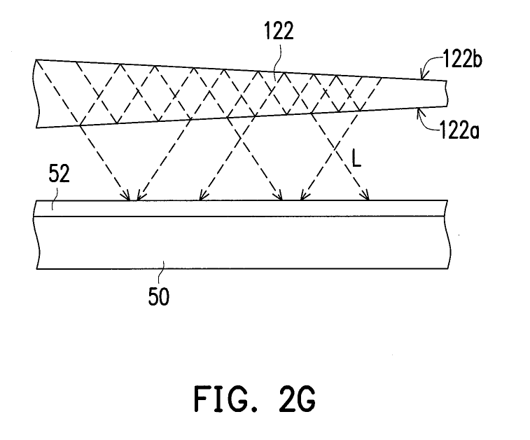

FIG. 2A to FIG. 2G are schematic diagrams of a transparent plate according to several embodiments of the invention. As shown in FIG. 2A, the transparent plate 122 further has at least one reflection layer 123 disposed on the side surface 122c of the transparent plate 122. The light L emitted from the light source device 128 shown in FIGS. 1A-1C enters the transparent plate 122. The light L is scattered toward the side surface 122c through the light incident surface 126, and is reflected from the side surface 122c to the first surface 122a by the reflection layer 123. And thus the light L emitted from the first surface 122a can enter the display region 52 of the mobile electronic device 50 to increase the utilization rate of the light L emitted from the light source device 128, i.e., increase the ratio of the light L entering the display region 52. Thereby, the illumination brightness and the illumination efficiency of the light source device 128 will be enhanced. In the embodiment, the reflection layer 123 may be metal or white reflective materials coated onto the side surface 122c; alternatively, the reflection layer 123 may be silver or white reflecting sheets adhered to the side surface 122c, which should not be construed as limitations to the invention. As shown in FIG. 2B, in another embodiment, there may be no reflection layer on the surface or the side surface of the transparent plate 122. In the invention, whether to form the reflection layer or not is determined according to users' requirements for illumination brightness.

Next, in FIG. 2C, the transparent plate 122 has an optical film 124, and the optical film 124 is disposed on the first surface 122a of the transparent plate 122, so as to guide the light L entering the transparent plate 122 to be emitted toward the display region 52. In another embodiment which is not illustrated, the optical film 124 can also be disposed on the second surface 122b of the transparent plate 122, so as to guide the light L entering the transparent plate 122 to be emitted toward the display region 52.

As shown in FIG. 2D, the transparent plate 122 may have a plurality of optical micro structures 125 formed on the first surface 122a of the transparent plate 122, so as to guide the light L entering the transparent plate 122 to be emitted toward the display region 52. Besides, the desired refraction path of the light L can be obtained through the appropriate adjustment in the shape of each of the optical micro structures 125, the size of each of the optical micro structure 125, and the distance among the optical micro structures 125. Hence, the transparent plate 122 and the light source device 128 may collectively act as a planar light source providing uniform brightness, and the brightness of images in the display region 52 is further enhanced. With reference to FIG. 2E and FIG. 2F, in another embodiment, the optical micro structures 125 can also be disposed on the second surface 122b of the transparent plate 122 or on the first surface 122a and the second surface 122b of the transparent plate 122 simultaneously, so as to guide the light L entering the transparent plate 122 to be emitted toward the display region 52 of the mobile electronic device 50.

In the aforementioned embodiments, the shape of each of the optical micro structures 125 is the cone shape, as shown in FIG. 2D, FIG. 2E, and FIG. 2F, but the invention is not limited thereto. Besides, in other embodiments which are not illustrated, the optical micro structures 125 can be additionally formed on the transparent plate 122, and methods of forming the optical micro structures 125 may include ink jet printing, screen printing, dry coating, wet coating, and so on.

As illustrated in FIG. 2G in another embodiment, the transparent plate 122 overall may be a wedge-shaped light guide plate, i.e., the first surface 122a and the second surface 122b are not parallel to each other. As illustrated in FIG. 2G, if the number of times of total reflection of the light L in the transparent plate 122 is less, the light L emitted from the transparent plate 122 is more uniform, and the illumination efficiency and brightness are higher. Besides, the design of the optical micro structures and the optical film may be adopted together with the wedge-shaped light guide plate provided in the embodiment. The light source device can be selectively disposed adjacent to other side surfaces of the transparent plate 122, and the reflection layer can also be selectively disposed on the side surface of the transparent plate according to actual requirements. The invention is not limited thereto.

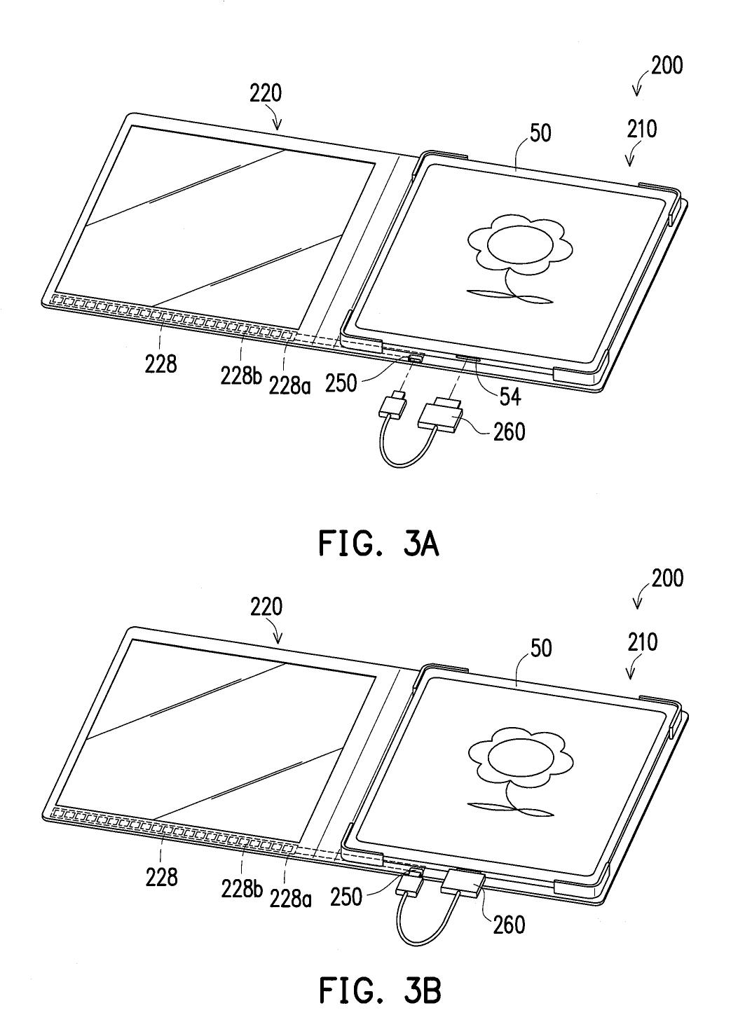

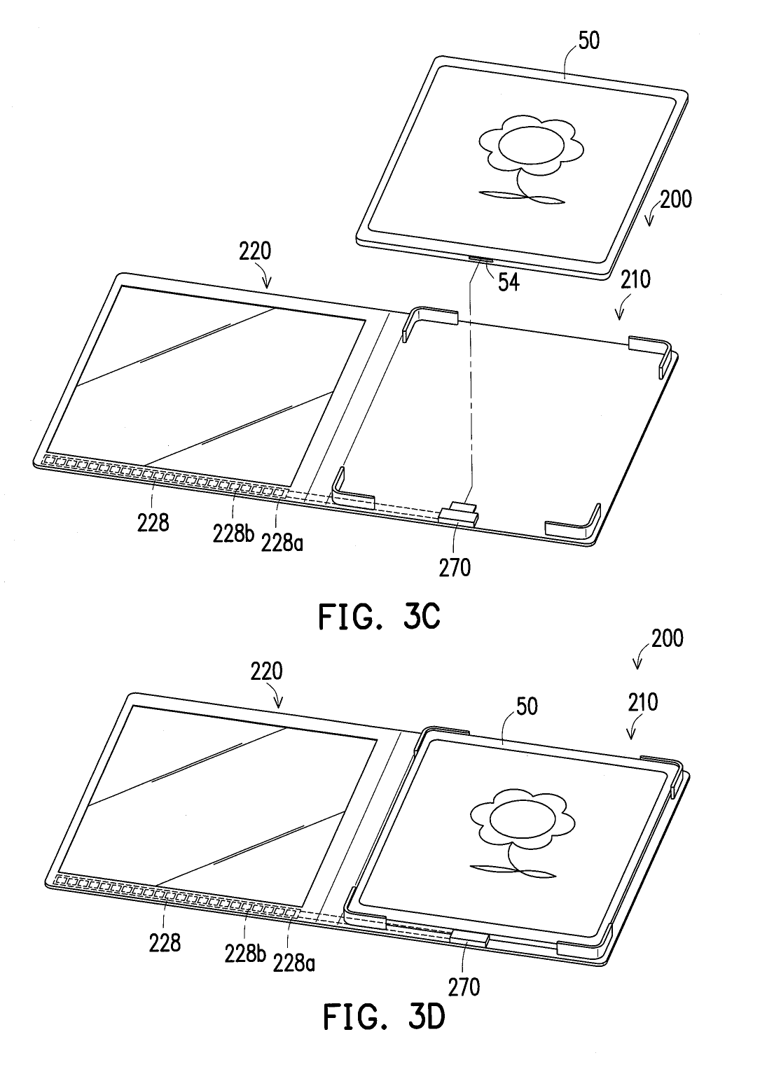

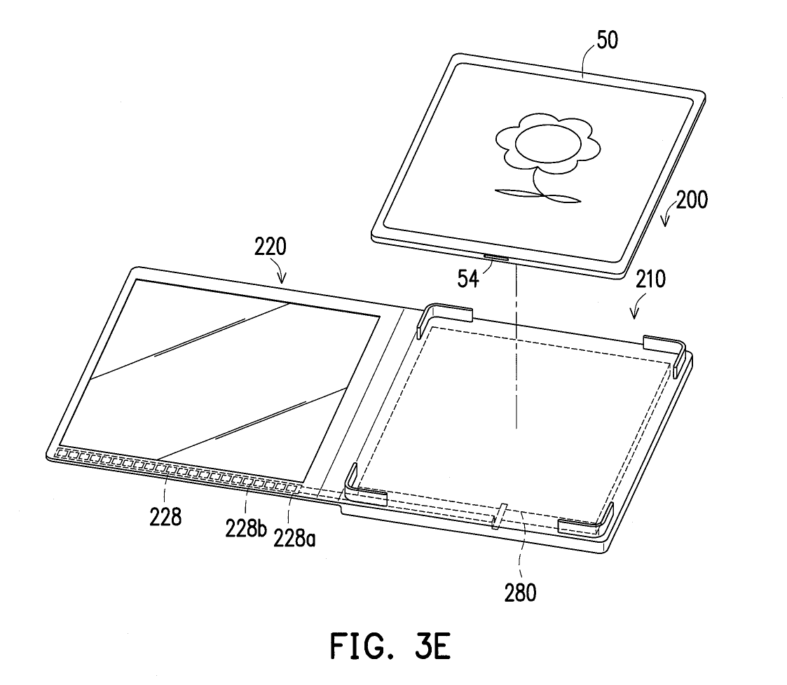

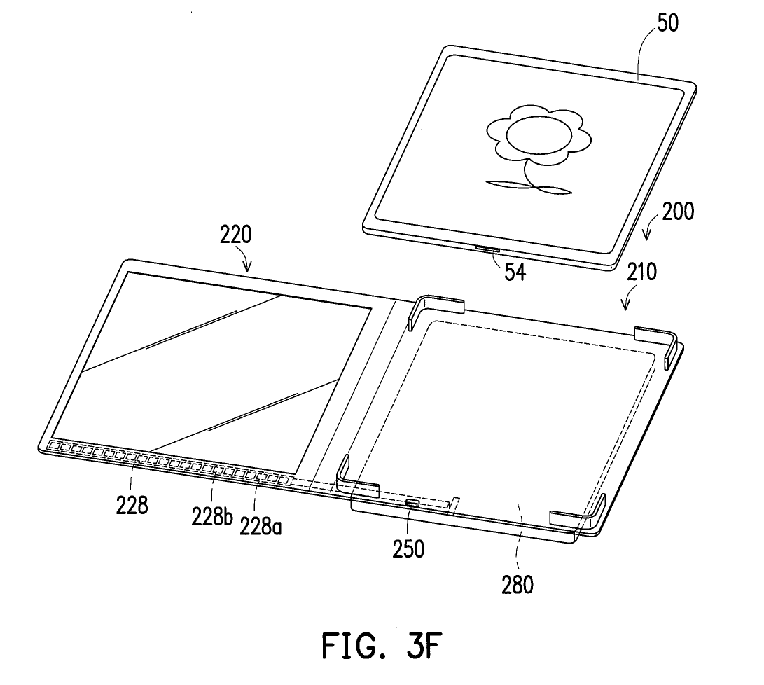

FIG. 3A to FIG. 3F are perspective views illustrating several implementations of a protective cover according to another embodiment of the invention. With reference to FIG. 3A and FIG. 3B, in the embodiment, the protective cover 200 is similar to the aforementioned protective cover 100, and the difference is that the protective cover 200 further includes an electrical connector 250 and a cable connector 260. The electrical connector 250 is disposed on the fixed side 210 or the movable side 220 and coupled to the light source device 228. On the other hand, the light source device 228 is electrically connected to the mobile electronic device 50 through two ends of the cable connector 260, wherein one end of the cable connector 260 is coupled to the electrical connector 250 electrically connected with the light source device 228, and the other end of the cable connector 260 is coupled to a socket connector 54 of the mobile electronic device 50. Through the electrical connector 250 and the cable connector 260, the protective cover 200 may provide the light source device 228 with the required electric power by means of the power supply storage device of the mobile electronic device 50 (e.g., a lithium battery or a nickel hydrogen battery) or a solar cell mounted on the mobile electronic device 50. Besides, electronic signals can also be transmitted from the mobile electronic device 50 to the light source device 228 through the cable connector 260, so as to directly control the switch of the light source device 228 or adjust the brightness of the light source device 228 through application program software installed in the mobile electronic device 50. In the embodiment, the electrical connector 250 may be a universal serial bus (USB) or another appropriate power supply transmission device. The connecting interface of the cable connector 260 is a micro universal serial bus (Micro-USB) or an integrated connecting interface adapted to connect the electrical connector and the socket connector made by different manufacturers of the mobile electronic devices.

Besides, in the embodiment, the light source device 228 may be a circuit board 228a with a plurality of light-emitting elements 228b. The light-emitting elements 228b are a plurality of LEDs, and the circuit board 228a may have flexibility. The light source device 228 can be disposed on the flexible portion or on a component of the protective cover 200; alternatively, the light source device 228 may be disposed on the protective cover characterized by flexibility as a whole.

As shown in FIG. 3C and FIG. 3D, the light source device 228 of the protective cover 200 and the mobile electronic device 50 may be coupled by means of the electrical connecting part 270 and the socket connector 54 of the mobile electronic device 50. The electrical connecting part 270 is disposed on the protective cover 200 and is coupled to the light source device 228. The electrical connecting part 270 may be the aforesaid USB or the electrical connecting interface which is adapted to accommodate the socket connectors of the mobile electronic devices 50 made by different manufacturers. The light source device 228 of the protective cover 200 can further obtain the electric power directly from the mobile electronic device 50 through the coupling between the electrical connecting part 270 and the socket connector 54 even though there is no other connecting cable, and thereby the portability and the convenience of the mobile electronic device 50 can both be enhanced.

Besides, as shown in FIG. 3E and FIG. 3F, an external power supply 280 can be selectively added to the protective cover 200. The external power supply 280 can be buried inside the fixed side 210 of the protective cover 200 or disposed adjacent to the fixed side 210 of the protective cover 200, e.g., on the rear of the fixed side 210 opposite to the front thereof where the mobile electronic device 50 is fixed, and the external power supply 280 is coupled to the electrical connector 250 electrically connected with the light source device 228 or directly coupled to the light-emitting elements 228b through the circuit board 228a. The external power supply 280 may be a mobile power supply, a normal dry cell, or a bendable solar cell. The invention is not limited thereto. Due to the external power supply 280, the powder endurance of the protective cover 200 and the mobile electronic device 50 in the outdoor environment can be increased even though there is no fixed power socket, and thus the convenience of using the protective cover 200 and the mobile electronic device 50 may be further enhanced.

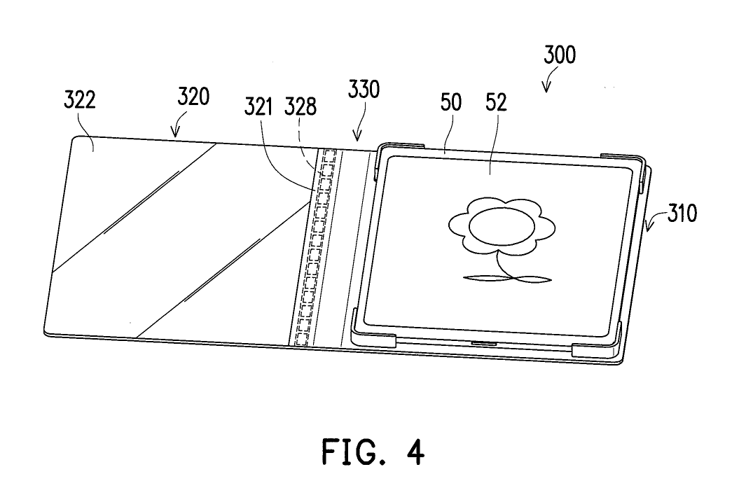

FIG. 4 is a perspective view of a protective cover according to another embodiment of the invention. With reference to FIG. 4, in another embodiment of the invention, the protective cover 300 is similar to the protective cover 100, while the difference is that there is no frame on the movable side 320 of the protective cover 300. In other words, the flexible portion 330 connects between the fixed side 310 and the movable side 320. Only one side of the transparent plate 322 on the movable side 320 is covered by the side bar 321, and the light source 328 is buried inside the side bar 321. The no-frame design of the protective cover 300 is capable of improving the deficiency of the frame of the conventional protective cover, such as dirt accumulation, the increase in the overall volume, thickness and weight of the conventional protective cover, and so on. Besides, this no-frame design embellishes the protective cover 300, reduces the visual influences of the frame of the protective cover 300 on the movable side 320 when users observe the display region 52 of the mobile electronic device 50, and complies with the current slim-border or no-frame design trend of the display region 52 of the mobile electronic device 50. Besides, in the embodiment, the flexible transparent plate 322 may be made of flexible materials including acrylic, polycarbonate (PC), and polyethylene terephthalate (PET). In addition, the fixed side 310 and the side bar 321 may also be made of flexible materials including rubber, silicone, and polymer materials, such that the entire protective cover 300 can be characterized by flexibility, and that the resultant protective cover 300 may be applied to various flexible mobile electronic devices that have been gradually developed to be mature.

To sum up, in the aforementioned embodiment of the invention, the protective cover provides not only the protection function through covering the mobile electronic device, but also the planar light source required by the mobile electronic device. Thereby, even though the ambient illumination is not given, the mobile electronic device can be used normally and constantly in no need of additional external light source devices. Besides, the light-emitting path of the transparent plate is adjusted by means of the reflection layer, the optical film, or the optical micro structures, so as to achieve the optimal light source device efficiency and enhance the brightness and uniformity of illumination. Furthermore, through different types of electrical connectors, the protective cover can provide the electric power required by the illumination light source device by means of the electrical energy storage device of the mobile electronic device instead of the external power supply, so as to reduce the necessity of carrying the mobile power supply and facilitate the use of the mobile electronic device and the protective cover. Besides, an external power supply can also be added to the protective cover to increase the power endurance of the protective cover and the mobile electronic device in the outdoor environment and further increase the convenience of using the protective cover and the mobile electronic device.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A protective cover, adapted to cover a mobile electronic device and illuminate a display region of the mobile electronic device, the protective cover comprising:
a fixed side, adapted to detachably fix the mobile electronic device;
a movable side, adapted to cover the display region of the mobile electronic device and having a transparent plate and a light source device, wherein the transparent plate has a first surface, a second surface opposite to the first surface, and at least one light incident surface connecting the first surface and the second surface, the light source device is disposed adjacent to the at least one light incident surface and generates light entering the transparent plate through the at least one light incident surface and then reaching the display region through the first surface of the transparent plate, and the display region receives the light and displays an image through the transparent plate; and
a flexible portion, bendably connecting the fixed side and the movable side.

2. The protective cover according to claim 1, wherein the movable side further includes:
a frame, connecting the flexible portion and surrounding the transparent plate.

3. The protective cover according to claim 2, wherein the light source device is buried inside the frame.

4. The protective cover according to claim 1, wherein the transparent plate has at least one reflection layer and at least one side surface connecting the first surface and the second surface, and the at least one reflection layer is disposed on the at least one side surface.

5. The protective cover according to claim 1, wherein the transparent plate has an optical film, and the optical film is disposed on the first surface or the second surface.

6. The protective cover according to claim 1, wherein the transparent plate has a plurality of optical micro structures disposed on the first surface, on the second surface, or on both the first surface and the second surface.

7. The protective cover according to claim 1, wherein the first surface and the second surface are not parallel to each other.

8. The protective cover according to claim 1, wherein the light source device includes a circuit board and a plurality of light-emitting elements mounted on the circuit board.

9. The protective cover according to claim 8, wherein the plurality of light-emitting elements are light emitting diodes.

10. The protective cover according to claim 1, wherein the light source device is a cold cathode fluorescent lamp.

11. The protective cover according to claim 1, further comprising:
an electrical connector, disposed on the fixed side or the movable side and coupled to the light source device, such that the electrical connector electrically connects the light source device with the mobile electronic device.

12. The protective cover according to claim 11, further comprising:
an external power supply, connected to the fixed side and coupled to the light source device and the electrical connector simultaneously.

13. The protective cover according to claim 1, further comprising:
a cable connector, coupled to the light source device and adapted to electrically connect the light source device with the mobile electronic device.

14. The protective cover according to claim 1, further comprising:
an external power supply, disposed on the fixed side and coupled to the light source device.

15. The protective cover according to claim 14, wherein the external power supply is buried inside the fixed side.

16. The protective cover according to claim 14, wherein the external power supply is disposed adjacent to the fixed side.

17. The protective cover according to claim 1, wherein the fixed side further includes:
at least one fixed portion, adapted to fix the mobile electronic device.
